(19) United States
(12) Patent Application Publication
(10) Pub. No.: US 2006/0193417 A1
(43) Pub. Date: Aug. 31, 2006

(54) Systems and methods for switching between redundant clock signals

(75) Inventor: Thomas Craig Jamison, Mount Airy, MD (US)

Correspondence Address: Dean D. Small;Armstrong Teasdale LLP, One Metropolitan Square, Suite 2600, St. Louis, MO, 63102, US

(73) Assignee: Tellabs Operations, Inc.

(21) Appl. No.: 11/065,868

(22) Filed: Feb. 25, 2005

(51) Int. Cl. H03D 3/24

(52) U.S. Cl. 375/376

(57) ABSTRACT

A system for switching between redundant clock signals is provided. The system includes a first clock signal generator configured to generate a first clock signal to provide a primary clock signal, a second clock signal configured to generate a second clock signal to provide a redundant clock signal, and a variable phase shift circuit configured to shift continuously a phase of the second clock signal to match a phase of the first clock signal to maintain the second clock signal in-phase with the first clock signal while the first clock signal is selected.

### BACKGROUND OF THE INVENTION

This invention relates generally to redundant clock systems and particularly to systems and methods for switching between redundant clock signals in data and communications networks.

In data and communication systems, when information is sent from a first location to a second location, the information is clocked at the first location is clocked at the first location by a first reference clock signal and the information received at the second location is clocked by a second reference clock signal. The second reference clock signal is initially tuned to be in-phase with the first reference clock signal. The first and second clock signals represent primary reference clock signals. A third reference clock signal may be provided as a redundant clock signal. The redundant clock signal may be applied at the first location, at the second location or alternatively at both the first and second locations. When a primary reference clock signal fails, the -information at the location of the failed reference clock signal is clocked by the redundant third reference clock signal.

However, conventional systems that offer redundant clocking have experienced certain disadvantages. For example, during the switching operation from the second reference clock signal to the third reference clock signal, the third reference clock signal may be out-of-phase with the second reference clock signal. When the third reference clock signal is out-of-phase, a phase transient or a glitch is experienced. A switching operation occurs to change from a primary reference clock signal to a redundant reference clock signal. A phase glitch occurs when a pulse of the third reference clock signal is missing or extends over an unusually small length of time comparison to a corresponding pulse of the second reference clock signal. A phase transient occurs when a pulse of the third reference clock signal occurs at a shifted position in comparison to a position of a corresponding pulse of the second reference clock signal. During the switching operation, when the third reference clock signal is out-of-phase, information received at the second location is not correctly clocked and must be discarded as a transmission error. Also, conventional systems experience a tuning time period, in which the third reference clock signal is tuned to become in-phase with the first or second reference clock signal. Information is also lost during the tuning time period.

In an attempt to reduce the loss of information, telecommunication standards, such as Telecordia GR-253, have set limits on a rate of phase change between the second and third reference clock signals during the switching operation. Nevertheless, regardless of the limits on the rate of phase change, transmission errors still occur when the third reference clock signal is out-of-phase with the second reference clock signal during the switching operation.

In yet another attempt to reduce the loss of information, first-in-first-out memories (FIFOs) are placed within the networks. Specifically, the FIFOs store a small amount of data, allowing the FIFOs to build up or be drained by a small magnitude of the phase difference between the second and third reference clocks without data loss or errors. Due to repeated switching between the second and third reference clocks, a magnitude of the phase difference between the second and third reference clocks exceeds a capacity of the FIFOs. When the capacity of the FIFOs is exceeded, the FIFOs either repeat (i.e., underflow) or discard (i.e., overflow) blocks of data to compensate for the phase difference between the second and third reference clocks. Underflow and overflow operations typically result in errors or loss of information within the networks. Very large FIFOs can reduce a probability of such errors or loss of information but the large FIFOs increase the delay through the networks. Delay is undesirable, so FIFO size is minimized. Thus, there is a trade-off between the FIFO size and the delay through the networks.

### BRIEF DESCRIPTION OF THE INVENTION

In one embodiment, a system for switching between redundant clock signals is provided. The system includes a first clock signal generator configured to generate a first clock signal to provide a primary clock signal, a second clock signal configured to generate a second clock signal to provide a redundant clock signal, and a variable phase shift circuit configured to shift continuously a phase of the second clock signal to match a phase of the first clock signal to maintain the second clock signal in-phase with the first clock signal while the first clock signal is selected.

In another embodiment, a system for switching between redundant clock signals is provided. The system includes a source clocked by a first clock signal and a second clock signal, and a variable phase shift module configured to shift a phase of the second clock signal before the first clock signal becomes inoperational. The variable phase shift module is configured to shift a phase of the first clock signal to generate a first phase-shifted signal. The variable phase shift module is configured to generate a second phase-shifted signal by shifting the phase of the second clock signal. The variable phase shift module is configured to match a phase of the second phase-shifted signal to a phase of the first phase-shifted signal by shifting the phase of the second clock signal.

In yet another embodiment, a method for switching between redundant clock signals is provided. The method includes generating a first phase-shifted signal by shifting a phase of a first clock signal, and generating a second phase-shifted signal by shifting the phase of a second clock signal, where the shifting the phase of the second clock signal includes shifting the phase of the second clock signal before the first clock signal becomes inoperational.

### BRIEF DESCRIPTION OF THE DRAWINGS

FIG. 1 is a block diagram of an embodiment of a communication system including a timing control module for switching between redundant clock signals.

FIG. 2 is a detailed block diagram of an embodiment of the timing control module illustrated in FIG. 1.

FIG. 3 is a flowchart of an embodiment of a method for switching between redundant clock signals.

FIG. 4 is a timing diagram illustrating another embodiment of the method for switching between redundant clock signals.

FIG. 5 is a timing diagram illustrating yet another embodiment of the method for switching between redundant clock signals.

FIG. 6 is a circuit diagram of an embodiment of a variable phase shift circuit included within the timing control module.

FIG. 7 is a block diagram of another embodiment of a variable phase shift circuit included within the timing control module.

FIG. 8 is a block diagram of an embodiment of an output clock phase-locked loop that may be included within the timing control module.

### DETAILED DESCRIPTION OF THE INVENTION

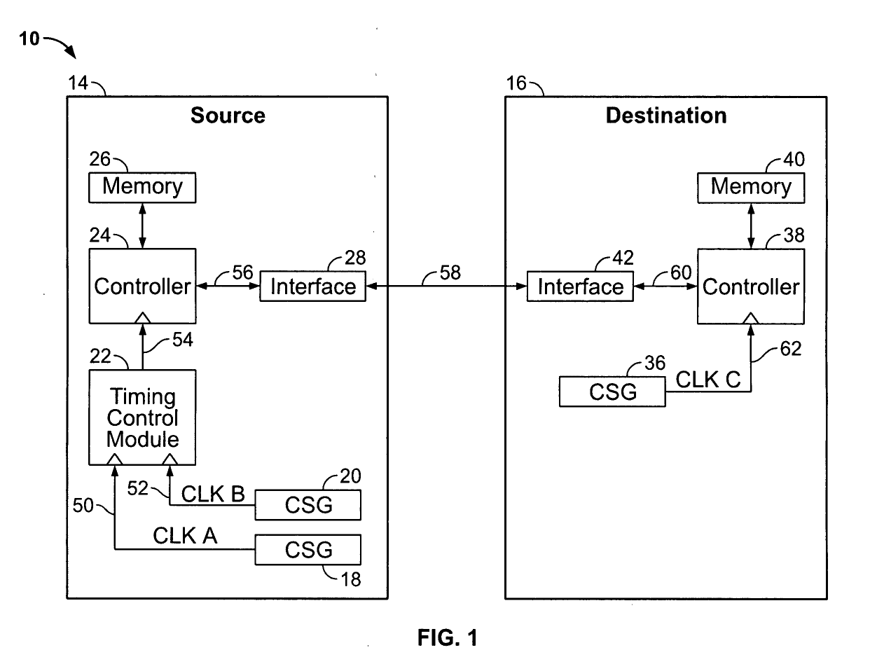

FIG. 1 is a block diagram of a communication system 10 for switching between redundant clock signals and formed in accordance with an embodiment of the present invention. Communication system 10 may represent a security system, an aerospace system, a telecommunications system, an avionics system, and a military system. Communication system 10 includes a source 14 and a destination 16. Source 14 is coupled to destination 16 via a link, such as, a wireless link, a fiber optic link, and a copper wire. Source 14 includes a clock signal generator (CSG) 18, a clock signal generator 20, a timing control module 22, a controller 24, a memory 26, such as a read-only memory or a random access memory, and an interface 28. The timing control module 22 and/or controller 24 may be implemented utilizing processors, microcontrollers, microcomputers, programmable logic controllers, discrete logic, firmware, application specific integrated circuits, and other programmable circuits. Interface 28 may represent a modem, clock signal generator 18 may represent a crystal oscillator or a building integrated timing source (BITS), and clock signal generator 20 may represent a crystal oscillator or a building integrated timing source. Destination 16 includes a clock signal generator 36, a controller 38, a memory 40, such as a read-only memory or a random access memory, and an interface 42. Interface 42 may represent a modem and clock signal generator 36 may represent a crystal oscillator or a building integrated timing source. Controller 38 may be implemented utilizing processors, microcontrollers, microcomputers, programmable logic controllers, discrete logic, firnware, application specific integrated circuits, and other programmable circuits.

Source 14 and destination 16 may be located at the same physical location, such as, a room or a building. In an alternative embodiment, source 14 and destination 16 may be located at different physical locations. In yet another alternative embodiment, source 14 and destination 16 may be located in different geographic areas, such as different states or different countries.

Clock signal generator 18 generates a clock A signal 50 and clock signal generator 20 generates a clock B signal 52. Timing control module 22 selects one of clock A signal 50 and clock B signal 52, generates a clock signal 54, and provides clock signal 54 to controller 24. Controller 24 reads information, such as addresses or data, via a link from memory 26 in-phase with clock signal 54 to generate an information signal 56 which is output to interface 28. Controller 24 outputs information signal 56 to interface 28 in-phase with clock signal 54. In an alternative embodiment, controller 24 outputs information signal 56 to interface 28 in-phase with clock signal 54 but does not read information from memory 26 in-phase with clock signal 54. Interface 28 modifies information signal 56 to generate a modified information signal 58 and transmits modified information signal 58 to interface. As an example, interface 28 may modulate an amplitude of information signal 56 to generate modified information signal 58. As another example, interface 28 may convert information signal 56 from an electrical to an optical signal and generate modified information signal 58 as an optical signal.

Interface 42 receives modified information signal 58, demodifies modified information signal 58 to generate information signal 60. As an example, interface 42 demodulates an amplitude of modified information signal 58 to generate information signal 60. As another example, interface 42 converts modified information signal 58 from an optical to an electrical signal and generates information signal 60. Clock signal generator 36 generates a clock C signal 62 and outputs clock C signal 62 to controller. Any of clock A signal 50, clock B signal 52, and clock C signal 62 may be a network clock signal, such as a T1 clock signal operating at a rate of 1.544 megahertz or an E1 clock signal operating at a rate of 2.048 megahertz. Controller 38 receives information signal 60 in-phase with a phase of clock C signal 62 to generate information and writes the information to memory 40 in-phase with the phase of clock C signal 62. In an alternative embodiment, controller 38 receives modified information signal 58 in-phase with a phase of clock C signal 62 to generate information signal 60 but does not write information to memory 40 in-phase with clock C signal 62.

A phase of clock A signal 50 is matched with the phase of clock C signal 62 before source 14 transmits information to destination 16. Controller 24 reads information from memory 26 and sends information signal 56 to interface 28 in-phase with clock A signal 50. Interface 28 receives information signal 56, generates modified information signal 58 from information signal 56, and transmits modified information signal 58 to interface 42. Interface 42 receives modified information signal 58 from interface 28 to generate information signal 60 and controller 38 receives information signal 60 from interface 42 in-phase with clock C signal 62.

Timing control module 22 matches a phase of clock B signal 52 to the phase of clock A signal 50 when the communication system 10 is initialized or turned on. Timing control module 22 continuously monitors the phase of clock A signal 50 and continuously automatically updates the phase of clock B signal 52 to remain in-phase or to match the phase of clock A signal 50.

The timing control module 22 continuously and automatically monitors a condition and quality of the clock A signal 50 and clock B signal 52. The timing control module 22 identifies failures (e.g., no clock signal or clock signal with frequency error) and determines that a particular clock signal has become inoperational. When clock A signal 50 becomes inoperational, controller 24 sends information signal 56 to interface 28 in-phase with clock signal 54 generated from clock B signal 52.

Clock A signal 50 may become inoperational when a state, such as, a frequency of clock A signal 50 does not match a state, such as frequency, of a pre-defined clock signal. Optionally, clock A signal 50 may become inoperational when the frequency of clock A signal 50 is not within pre-defined limits of the frequency of the pre-defined signal. Optionally, clock A signal 50 may become inoperational when the frequency of clock A signal 50 is zero.

In an alternative embodiment, destination 16 is clocked by clock A signal 50 and clock B signal 52 and source 14 is clocked by clock C signal 62. In yet another alternative embodiment, destination 16 is clocked by a redundant clock signal D when clock C signal 62 becomes inoperational.

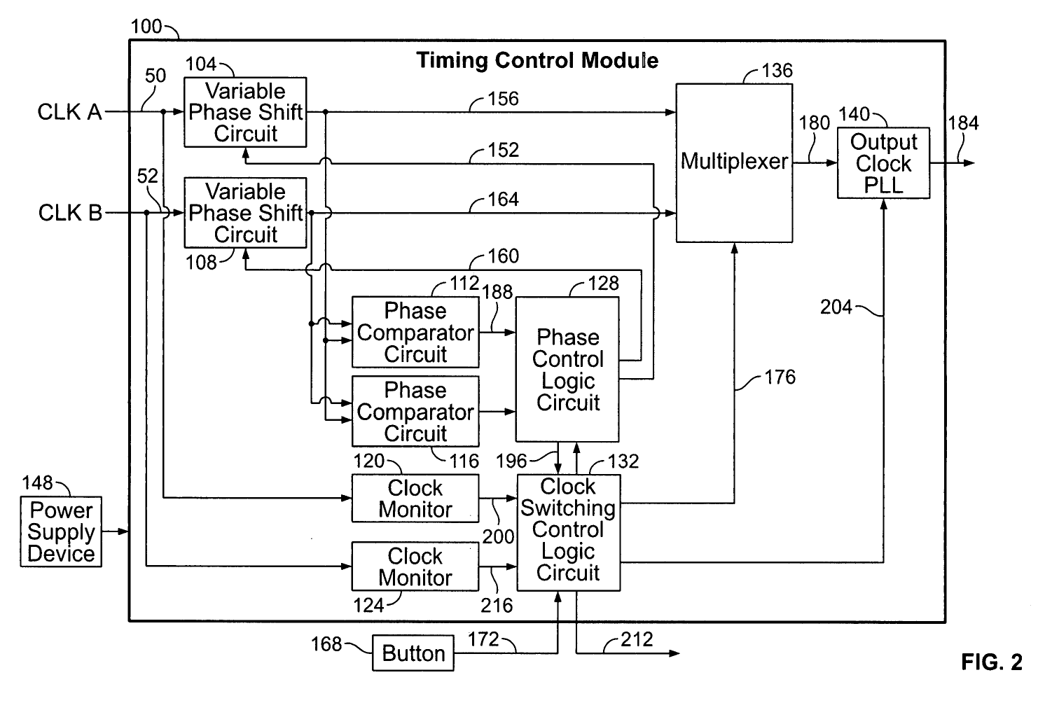

FIG. 2 is a detailed logic block diagram of a timing control module 100 formed in accordance with an embodiment of the present invention. Timing control module 100 may be used to implement an embodiment of timing control module 22 shown in FIG. 1. Timing control module 100 includes a variable phase shift circuit 104, a variable phase shift circuit 108, a phase comparator circuit 112, a phase comparator circuit 116, a clock monitor 120, a clock monitor 124, a phase control logic circuit 128, a clock switching control logic circuit 132, a multiplexer 136, and an output clock phase-locked loop (PLL) 140. Optionally, timing control module 100 may not include output clock PLL 140. Optionally, clock switching control logic circuit 132 may be formed to include clock monitors 120 and 124. Any of variable phase shift circuits 104 and 108 may be formed to include a resistor-capacitor (RC) variable phase shift circuit.

Any of phase comparator circuits 112 and 116 may include an MC 4044 circuit available from Motorola® corporation. Any of clock monitor circuits 120 and 124 may represent a frequency comparator circuit, such as the MC 4044 circuit. Phase control logic circuit 128 may represent a programmable logic device or a processor. Clock switching control logic circuit 132 may represent a programmable logic device or a processor. Output clock PLL 140 may represent a 4046 PLL available from Motorola® corporation.

A power supply device 148 provides power to timing control module to energize timing control module 100. When variable phase shift circuit 104 is energized by power supply device 148, variable phase shift circuit 104 receives clock A signal 50 and receives a phase-shift signal 152 to shift the phase of clock A signal 50 by zero. Variable phase shift circuit 104 shifts the phase of clock A signal 50 to generate phase-shifted-clock A signal 156. When variable phase shift circuit 104 is set to generate a zero phase shift, the phase-shifted-clock A signal 156 has the same phase as clock A signal 50.

When variable phase shift circuit 108 is energized by power supply device 148, variable phase shift circuit 108 receives clock B signal 52 and receives a phase-shift signal 160 to shift the phase of clock B signal 52 by zero. Variable phase shift circuit 108 shifts the phase of clock B signal 52 to generate a phase-shifted-clock B signal 164. When variable phase shift circuit 108 is set to generate a phase shift of zero, the phase-shifted-clock B signal 164 has the same phase as the phase of clock B signal 52.

A user may select a button 168 to generate an external-clock-select signal 172. When clock switching control logic circuit 132 receives external-clock-select signal 172, clock switching control logic circuit 132 outputs a selection signal 176. Multiplexer 136 receives selection signal 176, selects phase-shifted clock A signal 156, and outputs a selected clock signal 180. Multiplexer 136 outputs phase-shifted clock A signal 156 by selecting phase-shifted clock A signal 156. As explained below in detail, output clock PLL 140 receives selected clock signal 180 from multiplexer 136 and matches a phase of selected clock signal 180 to a feedback phase to generate an output clock signal 184 having the phase of selected clock signal 180.

Phase comparator circuit 112 receives phase-shifted clock A signal 156 and phase-shifted clock B signal 164, compares a phase of phase-shifted clock B signal 164 with the phase of phase-shifted clock A signal 156, and provides a phase comparison signal 188 to phase control logic circuit 128. An example of phase comparison signal 188 is a signal that represents a comparison of the phase, such as, forty-five degrees, of phase-shifted clock A signal 156 with the phase, such as, sixth degrees, of phase-shifted clock B signal 164. Phase control logic circuit 128 receives phase comparison signal 188 and generates phase-shift signal 160. Variable phase shift circuit 108 receives clock B signal 52 and based on phase-shift signal 160, shifts the phase of clock B signal 52 to match the phase of clock A signal 50. Variable phase shift circuit 108 matches the phase of clock B signal with clock A signal 50 before clock A signal 50 becomes inoperational. Phase comparator circuit 112 receives phase-shifted clock A signal 156 and phase-shifted clock B signal 164 with matching phases to generate phase comparison signal 188 indicating the match. Phase control logic circuit 128 receives phase comparison signal 188 indicating the match and sends a phase representation signal 196 to clock switching control logic circuit 132 to indicate that phase alignment has been completed.

Clock monitor 120 monitors the operation/state of clock A signal 50 by comparing the frequency of clock A signal 50 with the frequency of the pre-defined clock signal. When the frequency of the clock A signal 50 is not the same as or alternatively is not within the pre-defined limits of the frequency of clock A signal 50, the clock monitor 120 determines that clock A signal 50 is inoperational and clock monitor 120 generates a detection signal 200 indicating the inoperation.

Clock switching control logic circuit 132 receives detection signal 200 indicating the state of clock A signal 50. Detection signal 200 indicates that clock A signal 50 is inoperational. Output clock PLL 140 receives selected clock signal 180 having a low frequency, such as 8 kilohertz. Clock switching control logic circuit 132 outputs a tracking indication signal 204 indicating to discontinue tracking selected clock signal 180 when detection signal 200 indicating the inoperation of clock A signal 50 is received by clock switching control logic circuit 132 and selected clock signal 180 having the low frequency is received by output clock PLL 140. Output clock PLL 140 receives tracking indication signal 204 and selected clock signal 180, and discontinues tracking selected clock signal 180. Optionally, when clock switching control logic circuit 132 receives detection signal 200 indicating that clock A signal 50 is inoperational and output clock PLL 140 receives selected clock signal 180 having the low or high frequency, such as 125 megahertz, clock switching control logic circuit 132 outputs tracking indication signal 204 to discontinue tracking selected clock signal 180. Optionally, when clock switching control logic circuit 132 receives detection signal 200 indicating that clock A signal 50 is inoperational and output clock PLL 140 receives selected clock signal 180 having the high frequency, clock switching control logic circuit 132 does not output tracking indication signal 204 indicating to discontinue tracking selected clock signal 180.

Output clock PLL 140 receives tracking indication signal 204 indicating to discontinue tracking selected clock signal 180, which is phase-shifted clock A signal 156. Multiplexer 136 receives phase-shifted clock A signal 156 and selection signal 176 indicating to switch from outputting phase-shifted clock A signal 156 to outputting phase-shifted clock B signal 164. Multiplexer 136 receives phase-shifted clock A signal 156 and selection signal 176 indicating to switch when output clock PLL 140 receives tracking indication signal 204 indicating to discontinue tracking selected clock signal 180. Optionally, when clock A signal 50 becomes inoperational, regardless of whether output clock PLL 140 receives tracking indication signal 204 indicating to discontinue tracking selected clock signal 180, which is phase-shifted clock A signal 156, multiplexer 136 receives selection signal 176 indicating to switch from outputting phase-shifted clock A signal 156 to outputting phase-shifted clock B signal 164.

Clock switching control logic circuit 132 instructs multiplexer 136 to output phase-shifted clock B signal 164. When clock switching control logic circuit 132 instructs multiplexer 136 to output phase-shifted clock B signal 164, output clock PLL 140 receives selected clock signal 180 and tracking indication signal 204 indicating to track selected clock signal 180. Moreover, clock switching control logic circuit 132 outputs an auto-clock-switch-indication signal 212 when clock switching control logic circuit 132 instructs multiplexer 136 to output phase-shifted clock B signal 164. The auto-clock-switch-indication signal 212 indicates to the user that when clock A signal 50 is restored, multiplexer 136 receives selection signal 176 indicating to select phase-shifted clock A signal 156 and output clock PLL 140 receives tracking indication signal 204 indicating to track selected clock signal 180. Clock A signal 50 is restored when clock A signal 50 becomes operable. When the user selects button 168 to send external-clock-select signal 172 after the auto-clock-switch-indication signal 212 is generated and when clock A signal 50 is. restored, multiplexer 136 does not receive selection signal 176 indicating to select phase-shifted clock A signal 156 and output clock PLL 140 does not receive tracking indication signal 204 indicating to track phase-shifted clock A signal 156.

When clock A signal 50 is restored and before clock B signal 52 becomes inoperational, variable phase shift circuit 104 receives phase-shift signal 152 indicating to align the phase of clock A signal 50 with the phase of clock B signal 52. When clock switching control logic circuit 132 receives a detection signal 216 indicating that clock B signal 52 is inoperational and output clock PLL 140 receives selected clock signal 180 having the low frequency, such as 8 kilohertz, clock switching control logic circuit 132 outputs tracking indication signal 204 indicating to discontinue tracking selected clock signal 180. Output clock PLL 140 receives tracking indication signal 204 and selected clock signal 180, and discontinues tracking selected clock signal 180. In yet another alternative embodiment, when clock switching control logic circuit 132 receives detection signal 216 indicating that clock B signal 52 is inoperational and output clock PLL 140 receives selected clock signal 180 having the low or high frequency, such as 125 megahertz, clock switching control logic circuit 132 outputs tracking indication signal 204 to discontinue tracking selected clock signal 180. In still another alternative embodiment, when clock switching control logic circuit 132 receives detection signal indicating that clock B signal 52 is inoperational and output clock PLL 140 receives selected clock signal 180 having the high frequency, clock switching control logic circuit 132 does not output tracking indication signal 204 indicating to discontinue tracking selected clock signal 180.

When output clock PLL 140 receives tracking indication signal 204 indicating to discontinue tracking phase-shifted clock B signal 164, multiplexer 136 receives phase-shifted clock B signal 164 and selection signal 176 indicating to switch from outputting phase-shifted clock B signal 164 to outputting phase-shifted clock A signal 156. In an alternative embodiment, when clock B signal 52 becomes inoperational, regardless of whether output clock PLL 140 receives tracking indication signal 204 indicating to discontinue tracking phase-shifted clock B signal 164, multiplexer 136 receives selection signal 176 indicating to switch from outputting phase-shifted clock B signal 164 to outputting phase-shifted clock A signal 156.

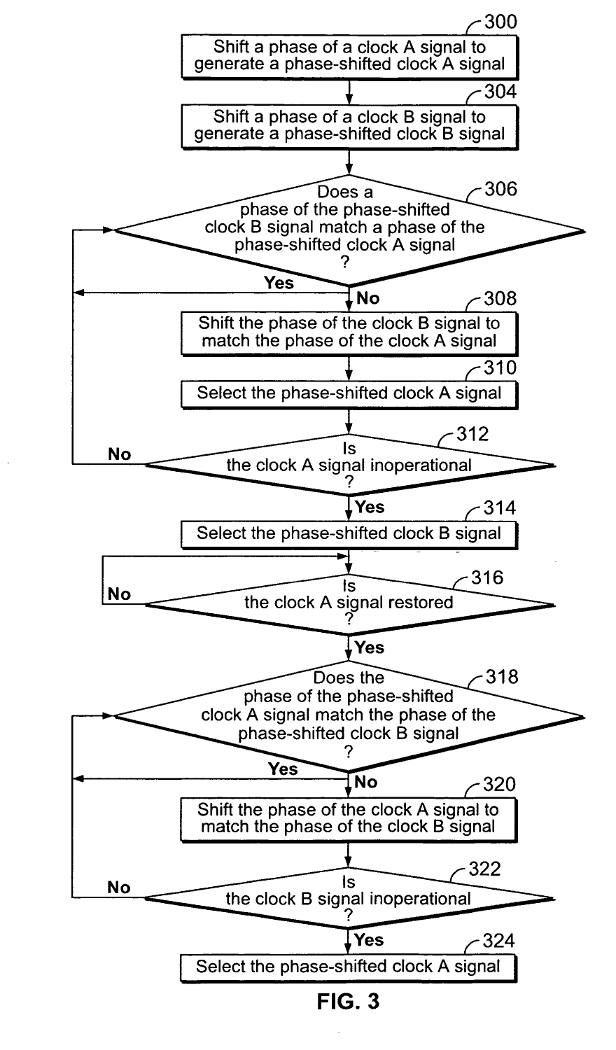

FIG. 3 is a flowchart of a method for switching between redundant clock signal in accordance with an embodiment of the present invention. Technique illustrated in FIG. 3, in some instances, may be performed sequentially, in parallel, or in an order other than that which is described. It should be appreciated that not all of the techniques described are required to be performed, that additional techniques may be added, and that some of the illustrated techniques may be substituted with other techniques.

The method includes shifting, at 300, the phase of clock A signal 50 to generate phase-shifted clock A signal 156 and shifting, at 304, the phase of clock B signal 52 to generate phase-shifted clock B signal 164. The method includes determining, at 306, whether the phase of phase-shifted clock B signal 164 matches the phase of phase-shifted clock A signal 156. If the phase of phase-shifted clock B signal 164 matches the phase of phase-shifted clock A signal 156, the method continues to determine, at 306, whether the phase of phase-shifted clock B signal 164 matches the phase of phase-shifted clock A signal 156. If the phase of phase-shifted clock B signal 164 does not match the phase of phase-shifted clock A signal 156, the method includes shifting, at 308, the phase of clock B signal 52 to match the phase of clock A signal 50. The method includes selecting, at 310, phase-shifted clock A signal 156.

The method includes determining, at 312, whether clock A signal 50 is inoperational. If clock A signal 50 is operational, the method includes determining, at 306, whether the phase of phase-shifted clock B signal 164 matches the phase of phase-shifted clock A signal 156. If clock A signal 50 is inoperational, the method includes selecting, at 314, phase-shifted clock B signal 164.

The method includes determining, at 316, whether clock A signal 50 is restored. If clock A signal 50 is not restored, the method includes continuing to determine, at 316, whether clock A signal 50 is restored. If clock A signal 50 is restored, the method includes determining, at 318, whether the phase of phase-shifted clock A signal 156 matches the phase of phase-shifted clock B signal 164. If the phase of phase-shifted clock A signal 156 matches the phase of phase-shifted clock B signal 164, the method continues to determine, at 318, whether the phase of phase-shifted clock A signal 156 matches the phase of phase-shifted clock B signal 164. If the phase of phase-shifted clock A signal 156 does not match the phase of phase-shifted clock B signal 164, the method includes shifting, at 320, the phase of clock A signal 50 to match the phase of clock B signal 52. The method includes determining, at 322, whether clock B signal 52 is inoperational. If clock B signal 52 is operational, the method includes determining, at 318, whether the phase of phase-shifted clock A signal 156 matches the phase of phase-shifted clock B signal 164. If clock B signal 52 is inoperational, the method includes selecting, at 324, clock A signal 50.

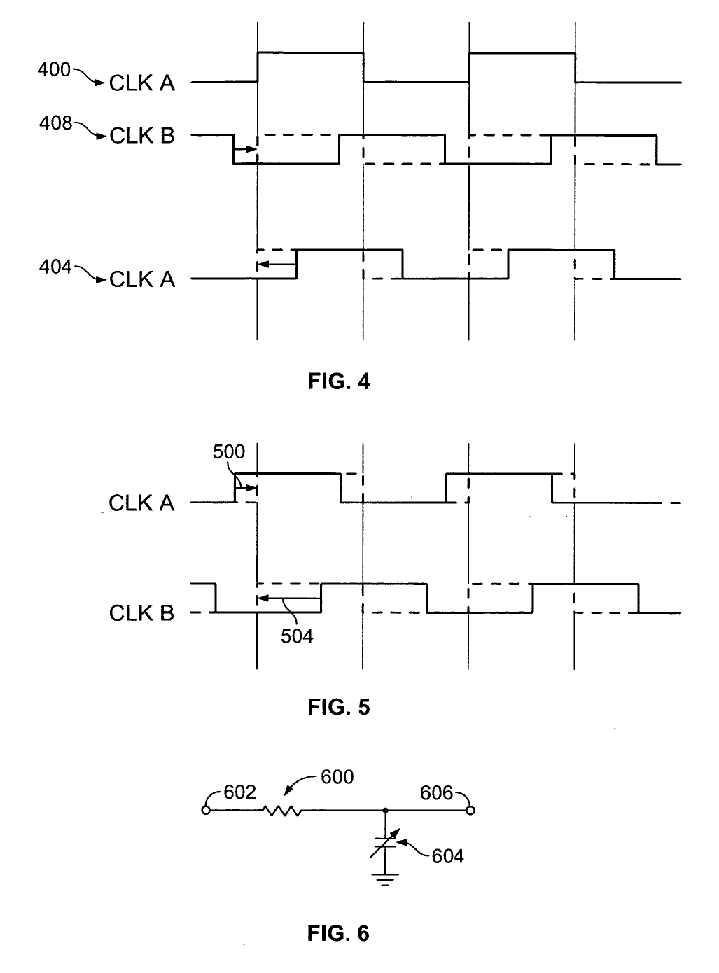

FIG. 4 shows a timing diagram illustrating a method for switching between redundant clock signals. Pulses 400 represent clock A signal 50 before clock A signal 50 becomes inoperational and pulses 404 represent clock A signal 50 after clock A signal 50 is restored.

Solid lines of pulses 408 represent the phase of clock B signal 52 before shifting clock B signal 52. Before clock A signal 50 becomes inoperational, the phase of clock B signal 52 is shifted to match the phase of pulses 400. Dotted lines of pulses 408 represent the phase of clock B signal 52 after shifting clock B signal 52.

Solid lines of pulses 404 represent the phase of clock A signal 50 before shifting clock A signal 50. When clock A signal 50 is restored and before clock B signal 52 becomes inoperational, the phase of pulses is shifted to match the phase of pulses 408 represented by dotted lines. Dotted lines of pulses 404 represent the phase of clock A signal 50 after shifting clock A signal 50.

FIG. 5 shows a timing diagram illustrating phase adjustment of clock A signal 50 and clock B signal 52. Solid lines of clock A signal 50 represent clock A signal 50 before shifting the phase of clock A signal 50 and solid lines of clock B signal 52 represent clock B signal 52 before shifting the phase of clock B signal 52. Dotted lines of clock A signal 50 represent clock A signal 50 after shifting the phase of clock A signal 50 and dotted lines of clock B signal 52 represent clock B signal 52 after shifting the phase of clock B signal 52. Variable phase shift circuit 104 matches the phase of clock A signal 50 with the phase of clock B signal 52 by shifting the phase of clock A signal 50 in a direction 500 opposite to a direction 504 in which variable phase shift circuit 108 shifts a phase of clock B signal 52 to match the phase of clock B signal 52 with the phase of clock A signal 50. For example, when variable phase shift circuit 104 increases the phase of clock A signal 50 by shifting the phase of clock A signal 50 in a positive direction, variable phase shift circuit 108 decreases the phase of clock B signal 52 by shifting the phase of clock B signal 52 in a negative direction. In an alternative embodiment, variable phase shift circuit 104 matches the phase of clock A signal 50 with the phase of clock B signal 52 by shifting the phase of clock A signal 50 in a direction same as a direction in which variable phase shift circuit 108 shifts a phase of clock B signal 52 to match the phase of clock B signal 52 with the phase of clock A signal 50. Phase control logic circuit 128 controls variable phase shift circuits 104 and 108 so that the variable phase shift circuits shift the phases of clock A signal 50 and clock B signal 52 in the same or alternatively opposite directions.

FIG. 6 is a circuit diagram of any of the RC variable phase shift circuit formed in accordance with an embodiment of the present invention. The RC variable phase shift circuit includes a resistor 600 coupled to an input 602, a variable capacitor 604, and an output 606. Variable capacitor 604 is coupled to a ground and output 606 is coupled to resistor 600. The RC variable phase shift circuit provides a desired phase shift by adjusting a capacitance of variable capacitor 604.

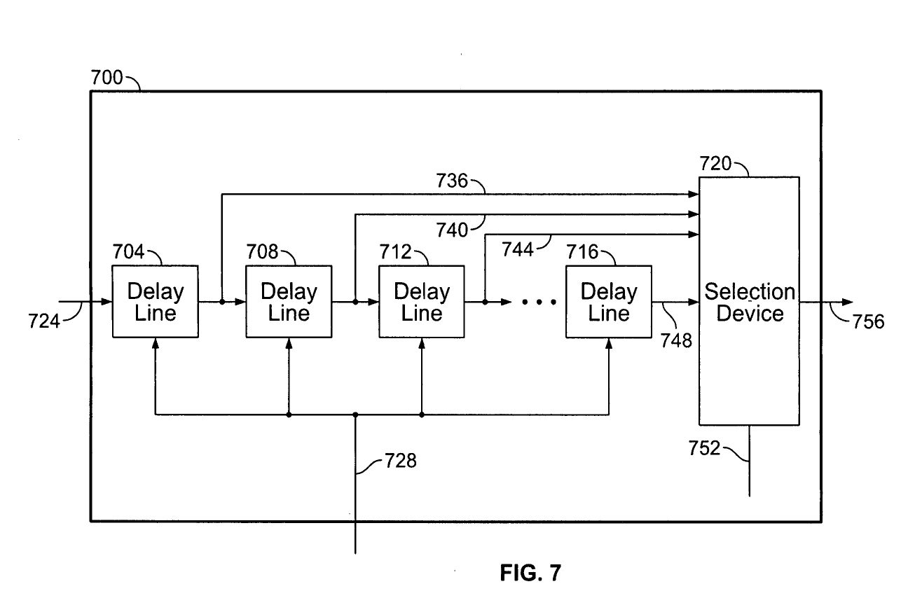

FIG. 7 is a block diagram of an embodiment of a variable phase shift circuit 700. Variable phase shift circuit 700 may be used to implement an embodiment of variable phase shift circuit 104 or of variable phase shift circuit 108. Variable phase shift circuit 700 includes a plurality of delay lines 704, 708, 712, and 716 and a selection device 720, such as a multiplexer. Delay lines 704, 708, 712, and 716 are coupled in series.

Variable delay line 700 receives a clock signal 724, such as clock A signal 50 or clock B signal 52. Phase control logic circuit 128 controls delay lines 704, 708, 712, and 716 via a control signal 728, and each delay line 704, 708, 712, and 716 provides the same amount of phase delay. Optionally, each delay line 704, 708, 712, and 716 provides a different amount of phase delay than at least one of the remaining delay lines. For example, each delay line 704, 708, and 712 provides a phase delay of m and delay line 716 provides a phase delay of n, where m is 180 degrees and n is 90 degrees.

Delay line 704 provides a phase-shifted clock signal 736 having a phase difference of m compared to a phase of clock signal 724. Delay line 708 provides a phase-shifted clock signal 740 having a phase difference of m compared to the phase of clock signal 736. Delay line 712 provides a phase-shifted clock signal 744 having a phase difference of m compared to the phase of clock signal 740. Delay line 716 provides a phase-shifted clock signal 748 having a phase difference of m compared to the phase of clock signal 744. A value of m can be 180 degrees. Thus, delay lines 704, 708, 712, and 716 provide a phase difference of Nm, where N is a number of the delay lines and an integer greater than zero. Optionally, variable phase shift circuit 700 generates a clock signal at the output of delay line 748 that has the same phase as clock signal 724. Phase control logic circuit 128 controls selection device 720 via a phase-shift select signal 752 to select any of phase-shifted clock signals 736, 740, 744, and 748 as an output phase-shifted clock signal 756.

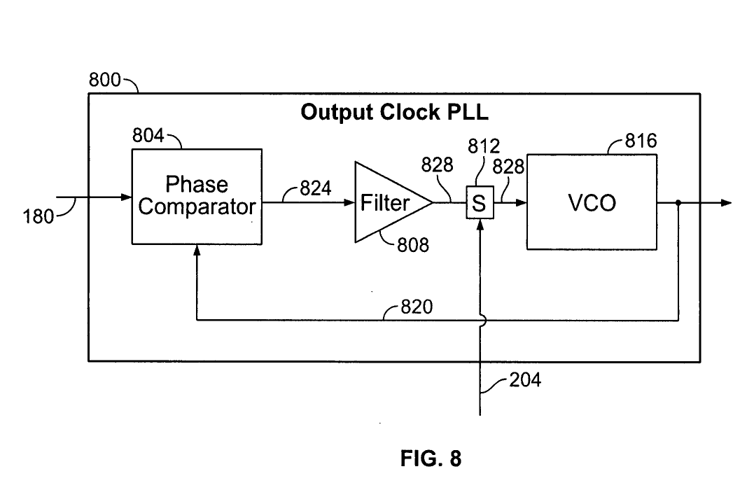

FIG. 8 shows an output clock PLL 800 formed in accordance with an embodiment of the present invention. Output clock PLL 800 is an example of output clock PLL 140 shown in FIG. 2. Output clock PLL 800 includes a phase comparator 804, a filter 808, a switch 812, and a voltage controlled oscillator (VCO) 816. Phase comparator 804 may include the MC 4044 circuit. Filter 808 may represent a low pass filter. Switch 812 may be an NPN bipolar junction transistor.

Phase comparator 804 receives selected clock signal 180 and compares a phase of selected clock signal 180 with the feedback phase of a feedback clock signal 820 to generate a phase error signal 824. Filter 808 receives phase error signal 824 and filters out the errors in phase error signal 824 to generate an error correction signal 828. Switch 812 receives error correction signal 828 and remains closed to provide error correction signal 828 to voltage controlled oscillator 816. Voltage controlled oscillator 816 receives error correction signal 828, which acts as a voltage signal that controls an oscillation generated by voltage controlled oscillator 816. The oscillation is feedback signal 820 having the feedback phase.

When switch 812 is receiving error correction signal 828 and receives tracking indication signal 204, switch 812 opens to discontinue providing error correction signal 828 to voltage controlled oscillator 816. Voltage controlled oscillator 816 receives tracking indication signal 204 indicating to open switch 812 and discontinues tracking selected signal 180 when switch 812 is open.

When switch 812 is open, voltage controlled oscillator 716 is not receiving error correction signal 828 and switch 812 receives tracking indication signal 204 indicating to close switch 812. When switch 812 receives tracking indication signal 204 indicating to close switch, error correction signal 828 is sent via switch 812 to voltage controller oscillator 816. Voltage controlled oscillator 816 receives tracking indication signal 204 indicating to close switch 812 and tracks selected signal 180 when switch 812 is open.

It is noted that when clock A signal 50 and clock B signal 52 are operable, the clock A signal 50 and clock B signal 52 have the same frequency. It is also noted that in an alternative embodiment, timing control module 22 receives any number, such as three or four, of multiple clock signals. Phases of remaining of the multiple clock signals are matched to a phase of an inoperational one of the multiple clock signals before the clock signal becomes inoperational. The multiple clock signals have the same frequency at all times when the multiple clock signals are operable.

While the invention has been described in terms of various specific embodiments, those skilled in the art will recognize that the invention can be practiced with modification within the spirit and scope of the claims.

What is claimed is:

1. A system for switching between redundant clock signals, the system comprising:
a first clock signal generator configured to generate a first clock signal to provide a primary clock signal;
a second clock signal configured to generate a second clock signal to provide a redundant clock signal; and
a variable phase shift circuit configured to shift continuously a phase of the second clock signal to match a phase of the first clock signal to maintain the second clock signal in-phase with the first clock signal while the first clock signal is selected.

2. A system in accordance with claim 1 wherein the variable phase shift circuit includes first and second variable phase shift circuits, the first variable phase shift circuit shifting the phase of the second clock signal in a direction opposite to a direction in which the second variable phase shift circuit shifts the phase of the first clock signal.

3. A system in accordance with claim 1 wherein the variable phase shift circuit is configured to shift a phase of the first clock signal to generate a first phase-shifted signal, the variable phase shift circuit configured to generate a second phase-shifted signal by shifting the phase of the second clock signal, and the variable phase shift circuit is configured to match a phase of the second phase-shifted signal to a phase of the first phase-shifted signal by shifting the phase of the second clock signal.

4. A system in accordance with claim 1 further comprising
an output clock phase-locked loop, wherein the variable phase shift circuit is configured to shift a phase of the first clock signal to generate a first phase-shifted signal; and
a clock switching control logic circuit configured to instruct the output clock phase-locked loop to discontinue tracking the first phase-shifted clock signal when the first clock signal is inoperational.

5. A system in accordance with claim 1 further comprising:
a multiplexer, wherein the variable phase shift circuit is configured to shift a phase of the first clock signal to generate a first phase-shifted signal and the variable phase shift circuit is configured to generate a second phase-shifted signal by shifting the phase of the second clock signal; and
a clock switching control logic circuit configured to control the multiplexer to output the first phase-shifted signal before the first clock signal becomes inoperational and to output the second phase-shifted clock signal when the first clock signal becomes inoperational.

6. A system in accordance with claim 1 further comprising:
an output clock phase-locked loop, wherein the variable phase shift circuit is configured to shift a phase of the first clock signal to generate a first phase-shifted signal and the variable phase shift circuit is configured to generate a second phase-shifted signal by shifting the phase of the second clock signal; and
a clock switching control logic circuit configured to provide an auto-clock-switch-indication signal when the first clock signal becomes inoperational and when the clock switching control logic circuit controls the output clock phase-locked loop to track the second phase-shifted clock signal.

7. A system in accordance with claim 1 further comprising:
a multiplexer, wherein the variable phase shift circuit configured to shift a phase of the first clock signal to generate a first phase-shifted signal;
an output clock phase-locked loop; and
a clock switching control logic circuit configured to control the multiplexer to output the first phase-shifted signal to the output clock phase-locked loop when the first clock signal is restored.

8. A system in accordance with claim I wherein the variable phase shift circuit is configured to shift a phase of the first clock signal to generate a first phase-shifted signal, the variable phase shift circuit is configured to generate a second phase-shifted signal by shifting the phase of the second clock signal, the variable phase shift circuit is configured to shift the phase of the first clock signal before the second clock signal becomes inoperational and when the first clock signal is restored, and the variable phase shift circuit is configured to match the phase of the first phase-shifted signal to the phase of the second phase-shifted signal by shifting the phase of the first clock signal before the second clock signal becomes inoperational.

9. A system for switching between redundant clock signals, the system comprising:
a source clocked by a first clock signal and a second clock signal; and
a variable phase shift module configured to shift a phase of the second clock signal before the first clock signal becomes inoperational, the variable phase shift module configured to shift a phase of the first clock signal to generate a first phase-shifted signal, the variable phase shift module configured to generate a second phase-shifted signal by shifting the phase of the second clock signal, and the variable phase shift module configured to match a phase of the second phase-shifted signal to a phase of the first phase-shifted signal by shifting the phase of the second clock signal.

10. A system in accordance with claim 9 wherein the variable phase shift module includes first and second phase shift circuits, the first phase shift circuit shifts the phase of the second clock signal in a direction opposite to a direction in which the second variable phase shift circuit shifts the phase of the first clock signal.

11. A system in accordance with claim 9 further comprising a phase comparator circuit configured to compare the phase of the first phase-shifted signal with the phase of the second phase-shifted signal.

12. A system in accordance with claim 9 further comprising an output clock phase-locked loop; and
a clock switching control logic circuit configured to instruct the output clock phase-locked loop to discontinue tracking the first phase-shifted clock signal when the first clock signal is inoperational.

13. A system in accordance with claim 9 further comprising:
a multiplexer; and
a clock switching control logic circuit configured to control the multiplexer to output the first phase-shifted signal before the first clock signal becomes inoperational and to output the second phase-shifted clock signal when the first clock signal becomes inoperational.

14. A system in accordance with claim 9 further comprising:
an output clock phase-locked loop; and
a clock switching control logic circuit configured to provide an auto-clock-switch-indication signal when the first clock signal becomes inoperational and when the clock switching control logic controls the output clock phase-locked loop to track the second phase-shifted clock signal.

15. A system in accordance with claim 9 further comprising:
a multiplexer;
an output clock phase-locked loop; and
a clock switching control logic circuit configured to control the multiplexer to output the first phase-shifted signal to the output clock phase-locked loop when the first clock signal is restored.

16. A system in accordance with claim 9 wherein the variable phase shift module shifts the phase of the first clock signal before the second clock signal becomes inoperational and when the first clock signal is restored, the variable phase shift module configured to match the phase of the first phase-shifted signal to the phase of the second phase-shifted signal by shifting the phase of the first clock signal before the second clock signal becomes inoperational.

17. A method for switching between redundant clock signals, the method comprising:
generating a first phase-shifted signal by shifting a phase of a first clock signal; and
generating a second phase-shifted signal by shifting the phase of a second clock signal, wherein the shifting the phase of the second clock signal includes shifting the phase of the second clock signal before the first clock signal becomes inoperational.

18. A method in accordance with claim 17 further comprising matching a phase of the second phase-shifted signal to a phase of the first phase-shifted signal by shifting the phase of the second clock signal.

19. A method in accordance with claim 17 wherein the shifting the phase of the second clock signal comprises shifting the phase of the second clock signal in a direction opposite to a direction in which the phase of the first clock signal is shifted.

20. A method in accordance with claim 17 further comprising:
monitoring a state of the first clock signal; and
switching from the first clock signal to the second signal when the state of the first clock signal becomes inoperational.
